(19) United States
(12) Patent Application Publication
(10) Pub. No.: US 2019/0376177 A1
(43) Pub. Date: Dec. 12, 2019

(54) VERTICAL SUBSTRATE HOLDER

(71) Applicant: CORNING INCORPORATED, CORNING, NY (US)

(72) Inventors: Bryce Patrick Butler, Elmira, NY (US); James Gregory Couillard, Ithaca, NY (US); Ming-Huang Huang, Ithaca, NY (US); Michael Aaron McDonald, Painted Post, NY (US); Donald Lynn Presher, Prattsburgh, NY (US); ChuanChe Wang, Horseheads, NY (US)

(21) Appl. No.: 16/463,220

(22) PCT Filed: Nov. 23, 2016
(86) PCT No.: PCT/US2017/062846

§ 371 Date: May 22, 2019

Related U.S. Application Data
(60) Provisional application No. 62/425,778, filed on Nov. 23, 2016.

(51) Int. Cl. C23C 14/50; C23C 16/458

(52) U.S. Cl. CPC C23C 14/505; C23C 16/4588

(57) ABSTRACT

Described herein are apparatuses for holding a substrate in a near vertical position, wherein the design minimizes substrate sag while allowing the substrate to expand and contract under varying thermal conditions. The apparatus minimizes the stress on the substrate, preventing breakage of or damage to the substrate while it undergoes coating and other thermal processes.

### BACKGROUND

This application claims the benefit of priority under 35 U.S.C. § 119 of U.S. Provisional Application Ser. No. 62/425,778, filed on Nov. 23, 2016, the content of which is relied upon and incorporated herein by reference in its entirety.

### FIELD

Described herein are apparatuses and methods for holding a substrate in a near vertical position that minimizes substrate sag while allowing the substrate to expand and contract under varying thermal conditions. The apparatus minimizes the stress on the substrate, preventing breakage of or damage to the substrate while it undergoes coating and other thermal processes.

### TECHNICAL BACKGROUND

Many applications involve coating substrates with thin films. For example, thin films for photovoltaic or electrochromic applications can be coated onto glass substrates. In many cases, the films are deposited onto the substrate under vacuum by physical vapor deposition (PVD), also known as sputter deposition. In PVD, a vapor of the material is produced, which is then deposited on the object which requires coating. PVD is advantageous in that it can provide a durable coating of many inorganic materials. However, because it is a vapor phase process, material is deposited on all parts within the chamber, which can lead to accumulation of particulate or unadhered material in the chamber and on substrate carriers. During deposition it is desirable to reduce non-vapor phase particles being incorporated into the film, as these can lead to electrical short defects in the finished device. The present disclosure describes modifications to the substrate carrier used in the deposition process to further reduce particle contamination.

### SUMMARY

Described herein are articles for holding large substrates in approximately vertical configurations. Such articles are designed to be used in coating devices and deposition processes and allow the substrates to be efficiently and evenly coated while preventing or minimizing contamination of the surface by extraneous particles that coat or are deposited in the coating chamber.

In an aspect (1), the disclosure provides an article comprising: a frame for holding a substrate in an approximately vertical configuration in a thin film deposition system containing a coating device, the frame being dimensionally larger than the substrate, and wherein the substrate has at least a front face, a back face, and at least one edge; the frame comprising: a flat frame section and a channel section, wherein when the article is in the thin film deposition system, the flat frame section is positioned between the coating device and at least part of the substrate, and the channel section is positioned adjacent to the at least one substrate edge; the flat frame section comprising a protective spacer that contacts the substrate on the front face, the protective spacer comprising a material that will not scratch the surface of the substrate; and two or more clamps comprising: a bumper that contacts the substrate on the back face, the bumper comprising a material that will not scratch the surface of the substrate; a rigid cantilever directly or indirectly connecting the channel section to the bumper; and a force-applying tensioner mechanism that provides a reaction force of less than 25 N on the substrate; wherein the article is designed so that when a substrate is in the frame, the substrate is held at an angle φ of from greater than 0° to about 10° forward tilt and experiences a maximum principal stress of less than 100 MPa while undergoing thermal variations of from 1°/min to 40°/min over a range of from 0° C. to 400° C. In an aspect (2), the disclosure provides the article of aspect (1), wherein the bumper and protective spacer are made of an organic polymer. In an aspect (3), the disclosure provides the article of aspect (1) or aspect (2), wherein the maximum principal stress is 80 MPa or less. In an aspect (4), the disclosure provides the article of any of aspects (1)-(3), wherein the reaction force is less than 15 N. In an aspect (5), the disclosure provides the article of any of aspects (1)-(4), wherein the substrate is held at an angle φ of from greater than 0° to about 3° forward tilt. In an aspect (6), the disclosure provides the article of any of aspects (1)-(5), wherein the two or more clamps are each rotatable on an axis orthogonal to the substrate faces. In an aspect (7), the disclosure provides the article of any of aspects (1)-(6), wherein an imaginary line orthogonal to the back face of the substrate and passing through a point where the bumper contacts the substrate would also pass through the protective spacer.

In an aspect (8), the disclosure provides an article comprising: a frame for holding a substrate in an approximately vertical configuration in a thin film deposition system containing a coating device, the frame being dimensionally larger than the substrate, and wherein the substrate has at least a front face, a back face, and at least one edge; the frame comprising: a flat frame section, wherein when the article is in the thin film deposition system, the flat frame section is positioned between the coating device and at least part of the substrate; the flat frame section comprising a protective spacer that contacts the substrate on the front face, the protective spacer comprising a material that will not scratch the surface of the substrate; and two or more clamps comprising: a cantilever spacer directly or indirectly connecting the cantilever to the frame; an optional bumper that contacts the substrate on the back face, the bumper comprising a material that will not scratch the surface of the substrate; a rigid cantilever directly or indirectly connecting the cantilever spacer to the bumper, wherein when the optional bumper is not present, the rigid cantilever contacts the substrate on the back face and comprises a material that will not scratch the surface of the substrate; and a force-applying tensioner mechanism that provides a reaction force of less than 25 N on the substrate; wherein the article is designed so that when a substrate is in the frame, the substrate is held at an angle φ of from greater than 0° to about 10° forward tilt and experiences a maximum principal stress of less than 100 MPa while undergoing thermal variations of from 5°/min to 40°/min over a range of from 0 ° C. to 300 ° C. In an aspect (9), the disclosure provides the article of aspect (8), wherein the bumper and protective spacer are made of an organic polymer. In an aspect (10), the disclosure provides the article of aspect (8) or aspect (9), wherein the maximum principal stress is 80 MPa or less. In an aspect (11), the disclosure provides the article of any of aspects (8)-(10), wherein the reaction force is less than 15 N. In an aspect (12), the disclosure provides the article of any of aspects (8)-(11), wherein the substrate is held at an angle φ of from greater than 0° to about 3° forward tilt. In an aspect (13), the disclosure provides the article of any of aspects (8)-(12), wherein the two or more clamps are each rotatable on an axis orthogonal to the substrate faces. In an aspect (14), the disclosure provides the article of any of aspects (8)-(13), wherein an imaginary line orthogonal to the back face of the substrate and passing through a point where the bumper contacts the substrate would also pass through the protective spacer.

In an aspect (15), the disclosure provides an article comprising: a frame for holding a substrate in an approximately vertical configuration in a thin film deposition system containing a coating device, the frame being dimensionally larger than the substrate, and wherein the substrate has at least a front face, a back face, and at least one edge; the frame comprising: a flat frame section, wherein when the article is in the thin film deposition system, the flat frame section is positioned between the coating device and at least part of the substrate; the flat frame section comprising a protective spacer that contacts the substrate on the front face, the protective spacer comprising a material that will not scratch the surface of the substrate; and two or more clamps comprising: an optional bumper that contacts the substrate on the back face; an organic polymer cantilever incorporating a cantilever spacer and that directly or indirectly connects the frame to the bumper, wherein when the optional bumper is not present, the rigid cantilever contacts the substrate on the back face and comprises a material that will not scratch the surface of the substrate; and an optional force-applying tensioner mechanism that provides a reaction force of less than 25 N on the substrate; wherein the article is designed so that when a substrate is in the frame, the substrate is held at an angle φ of from greater than 0° to about 10° forward tilt and experiences a maximum principal stress of less than 100 MPa while undergoing thermal variations of from 5°/min to 40°/min over a range of from 0 ° C. to 300 ° C. In an aspect (16), the disclosure provides the article of aspect (15), wherein the bumper and protective spacer are made of an organic polymer. In an aspect (17), the disclosure provides the article of aspect (15) or aspect (16), wherein the maximum principal stress is 80 MPa or less. In an aspect (18), the disclosure provides the article of any of aspects (15)-(17), wherein the reaction force is less than 15 N. In an aspect (19), the disclosure provides the article of any of aspects (15)-(18), wherein the substrate is held at an angle φ of from greater than 0° to about 3° forward tilt. In an aspect (20), the disclosure provides the article of any of aspects (15)-(19), wherein the two or more clamps are each rotatable on an axis orthogonal to the substrate faces. In an aspect (21), the disclosure provides the article of any of aspects (15)-(20), wherein an imaginary line orthogonal to the back face of the substrate and passing through a point where the bumper contacts the substrate would also pass through the protective spacer.

Additional features and advantages will be set forth in the detailed description which follows, and in part will be readily apparent to those skilled in the art from the description or recognized by practicing the embodiments as described in the written description and claims hereof, as well as in the appended drawings.

It is to be understood that both the foregoing general description and the following detailed description are merely exemplary, and are intended to provide an overview or framework for understanding the nature and character of the invention.

### BRIEF DESCRIPTION OF THE DRAWINGS

The accompanying drawings are included to provide a further understanding of the description, and are incorporated in and constitute a part of this specification. The drawings are not necessarily to scale, and sizes of various elements may be distorted for clarity. The drawings illustrate one or more embodiment(s) and together with the description serve to explain the principles and operation of the embodiments.

FIG. 1 is a cross-section of an embodiment described herein. The cross section of top part of carrier 100 is shown as 100A (to distinguish it from the lower section which is shown supporting substrate 170 in FIG. 1). The carrier 100 (as shown in 100A) comprises a frame 120, a force applying tensioner 121, a rigid cantilever 122, a bumper 123, and a protective spacer 124. As shown in the figure, a substrate 170 can be placed in and held by the holder with the bumper 123, 143 and the protective spacer 124, 144 being the contact points between the substrate and the holder.

FIGS. 2A-2F provide alternative embodiments of the holder described herein

FIG. 3 provides a perspective drawing of the holder with the various components broken out for clarity.

FIG. 4 shows a perspective drawing of an embodiment where the entire carrier 100 is shown in combination with a substrate 170 and a number of rigid cantilevers in position for holding the substrate 170.

FIG. 5 is a graph comparing the reaction force (combined effect of the coefficient of friction and the clamp force) to the maximum principal stress that the substrate undergoes. The maximum principal stress can be maintained in the “safest” region (the circled area) by not selecting excessive spring weight.

### DETAILED DESCRIPTION

Before the present materials, articles, and/or methods are disclosed and described, it is to be understood that the aspects described below are not limited to specific compounds, synthetic methods, or uses as such may, of course, vary. It is also to be understood that the terminology used herein is for the purpose of describing particular aspects only and is not intended to be limiting.

In this specification and in the claims that follow, reference will be made to a number of terms that shall be defined to have the following meanings:

Throughout this specification, unless the context requires otherwise, the word “comprise,” or variations such as “comprises” or “comprising,” will be understood to imply the inclusion of a stated integer or step or group of integers or steps but not the exclusion of any other integer or step or group of integers or steps.

It must be noted that, as used in the specification and the appended claims, the singular forms “a,” “an” and “the” include plural referents unless the context clearly dictates otherwise. Thus, for example, reference to “a carrier” includes mixtures of two or more such carriers, and the like.

“Optional” or “optionally” means that the subsequently described event or circumstance may or cannot occur, and that the description includes instances where the event or circumstance occurs and instances where it does not.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed.

When the term “about” is used in describing a value or an end-point of a range, the disclosure should be understood to include the specific value or end-point referred to. When a numerical value or end-point of a range does not recite “about,” the numerical value or end-point of a range is intended to include two embodiments: one modified by “about,” and one not modified by “about.” It will be further understood that the endpoints of each of the ranges are significant both in relation to the other endpoint, and independently of the other endpoint.

Disclosed are articles and components that may be used for, may be used in conjunction with, may be used in preparation of, or are products of the disclosure. It should be understood that when combinations, subsets, interactions, groups, etc. of these materials are disclosed that while specific reference of each various individual and collective combinations and permutation of these compounds may not be explicitly disclosed, each may be specifically contemplated and described herein. Thus, if a class of items A, B, and C are disclosed as well as a class of items D, E, and F and an example of a combination A-D may be disclosed, then even if each is not individually recited, each may be individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these may be also specifically contemplated and disclosed. Thus, for example, the sub-group of A-E, B-F, and C-E are specifically contemplated and should be considered disclosed from disclosure of A, B, and C; D, E, and F; and the example combination A-D.

Many applications involve thin film coatings on glass. One particular application is electrochromic films, such as those used for smart windows. These films produce a tinting effect when a voltage is applied across them. This condition has the effect of reducing light transmission and heat transmission for the window. The film stack is deposited onto the substrate (e.g., glass) under vacuum by physical vapor deposition (PVD), also known as sputter deposition. For PVD coating of large thin substrates, the glass/substrate is typically fixtured in a horizontal or vertical orientation wherein the back or uncoated surface of the glass can be supported. The device in which the glass is fixtured into is typically referred to as a carrier. If the glass is in a near vertical orientation the fixture may be tilted back to allow the glass to be supported by the back of the carrier and the glass shape is maintained nearly flat, allowing it to maintain a uniform distance to the PVD material targets which improves the uniformity of the coating on the surface.

Some PVD coater designs utilize “V-type” carriers. “V-type” carriers allow the glass to tilt toward the targets. By tilting the glass so that the face is slightly facing downward minimizes the potential for any stray particles to be fixed the substrate face during the coating process and thus, reduces defects. However, as substrate sizes continue to get larger and substrate thicknesses decrease, use of “V-type” carriers has resulted in substrate sag impacting film uniformity. As a result, there has been a shift from “V-type” carriers to vertical and “A-type” carriers (tilt back away from PVD targets). While “A-type” and vertical carriers solved the sag issue in thin substrates, they re-introduced the problem of particle contamination that “V-type” configurations were overcoming. Therefore, there remains an unmet need to design a carrier that prevents or minimizes particle contamination of large thin substrates when these substrates undergo thin film deposition.

Irrespective of the carrier type, the substrate is normally clamped into the carrier near the perimeter region of the glass, which is often considered non-quality portion of the product as it will be removed or hidden by the window frame. PVD processes can heat the substrate up to 400° C. or more. When the carrier, typically metal, and the substrate, often glass, undergo large temperature variations, the different in the coefficient of thermal expansion between the materials creates high stress levels in the substrate. These stresses can be both in plane (stretch) and out of plane (bending, torsional, rotational, etc.). The maximum principal stress value of the material is found from the Cauchy stress theorem, which states that the state of stress at a point in a body is defined by all the stress vectors T⁽ⁿ⁾ associated with all planes that pass through that point (see, e.g., Fridtjov Irgens, Continuum Mechanics, Sec. 3.2.3, (Springer, 2008), herein incorporated by reference). Cauchy's stress theorem states that there exists a second-order tensor field σ(x, t), called the Cauchy stress tensor, independent of a unit-length direction vector n, such that T is a linear function of n:

T⁽ⁿ⁾=n·σ or Tⱼ⁽ⁿ⁾=σᵢⱼnᵢ.

This equation implies that the stress vector T⁽ⁿ⁾ at any point P in a continuum associated with a plane with normal unit vector n can be expressed as a function of the stress vectors on the planes perpendicular to the coordinate axes, i.e. in terms of the components σᵢⱼ of the stress tensor a, which consists of nine components σᵢⱼ that completely define the state of stress at a point inside a material in the deformed state, placement, or configuration:

$$σ = [ \begin{matrix}{σ}_{11} & {σ}_{12} & {σ}_{13} \\ {σ}_{21} & {σ}_{22} & {σ}_{23} \\ {σ}_{31} & {σ}_{32} & {σ}_{33}\end{matrix} ] ≡ [ \begin{matrix}{σ}_{xx} & {σ}_{xy} & {σ}_{xz} \\ {σ}_{yx} & {σ}_{yy} & {σ}_{yz} \\ {σ}_{zx} & {σ}_{zy} & {σ}_{zz}\end{matrix} ] ≡ [ \begin{matrix}{σ}_{x} & {τ}_{xy} & {τ}_{xz} \\ {τ}_{yx} & {σ}_{y} & {τ}_{yz} \\ {τ}_{zx} & {τ}_{zy} & {σ}_{z}\end{matrix} ]$$

In some embodiments, the maximum principal stress is less than 100 MPa, less than 90, less than 80, less than 70, less than 60, less than 50, less than 40 or less than 30 MPa. In some embodiments, the maximum principal stress if from 30-100 MPa, 40-100 MPa, 50-100 MPa, 60-100 MPa, 70-100 MPa, 80-100 MPa, 60-90 MPa, 70-90 MPa, 50-80 MPa, 60-80 MPa, or 50-70 MPa.

The present disclosure provides an improvement to the current design methods for holding large, thin substrates in vertical configurations for coating applications. It does so by combining a “V-type” configuration for the substrate with improved clamping mechanisms that provide the necessary support to eliminate/reduce substrate sag, while at the same time allowing the glass to move within the carrier such that stresses from thermal variations are minimized. The advantages of the embodiments described herein are that they allow for continued use of “V-type” coater designs with thinner substrates, allows for use of larger, thinner substrates with high quality coatings, minimizes scratching/damage to the substrate, allows quick loading and unloading of the substrate into the carrier, and maximizes the quality area of the coated glass by only contacting the glass near the edge.

As noted above, one method of minimizing particulate contamination is to tilt the substrate. In the case of a thick, rigid substrate, such as a thick (2 mm or greater) soda lime glass substrate, it is possible to tilt it quite significantly without inducing out-of-plane sag. However, with the drive towards thinner and lighter materials and devices, there is an increased interest in thinner, and sometimes flexible, substrates. In these cases, out-of-plane sag is a real concern because it can have a negative impact on deposition uniformity. The impact of sag becomes more pronounced as the substrate grows larger and thinner.

In order to minimize the impact of sag on substrates of any thickness, the necessary tilt to minimize particle deposition has been calculated using a simple collision model. Consider a particle which becomes dislodged within the vacuum chamber and begins falling due to gravity. As the particle passes through the stream of atoms being deposited onto the glass it may undergo momentum transfer due to an elastic collision with an incoming atom. Let m₁ be the mass of the incident atom and m₂ the mass of the particle. Conservation of momentum and energy give:

m₁u₁+m₂u₂ (before collision)=m₁v₁+m₂v₂ (after collision)

1/2m₁u₁²+1/2m₂u₂²=1/2m₂u₂²=1/2m₁v₂²+1/2m₂v₂²

Assuming the falling particle has no initial forward motion (u₂=0) this can be simplified to:

$${m}_{2} {v}_{2} = \frac{2 {m}_{1} {m}_{2} {u}_{1}}{{m}_{2} + {m}_{2}}$$

The bombardment (forward) force on the particle is thus:

$${F}_{s} - ( \frac{2 {m}_{1} {m}_{2} {u}_{1}}{{m}_{1} + {m}_{2}} ) v$$

where v is the collision frequency. After the collision the angle of the particle's trajectory with respect to vertical is the ratio of the bombardment force to the gravitational force, or:

$$θ = atan [ \frac{{F}_{B}}{{F}_{G}} ] = atan [ \frac{2 {m}_{1} {u}_{1} v}{g ( {m}_{1} + {m}_{2} )} ] .$$

Using reasonable values for the input parameters (5 μm ITO particle, W atoms moving at 250 m/s, and a collision frequency based on 2 nm/s tungsten deposition rate) we arrive at a trajectory angle of ˜3°. However it has been found that tilt alone is not sufficient to eliminate particle contamination. We can further reduce particle contamination by preventing the particles from becoming dislodged within the vacuum chamber in the first place.

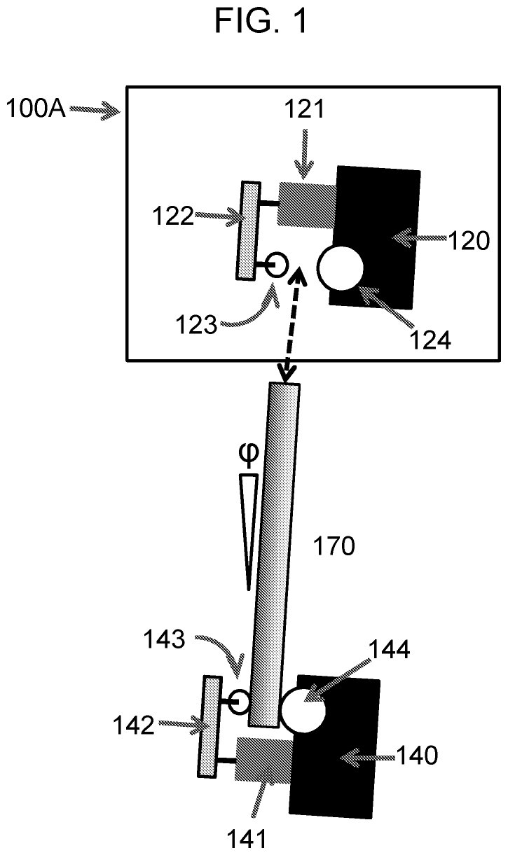

One way to reduce particles is by modifying the carrier used to hold the substrate in the deposition system. Looking at FIG. 1, the substrate, 170, is potentially vulnerable to particles raining down from the top section of the frame, 120. The carrier 100, via the frame 120, surrounds the substrate, 170, and is necessary both to hold the substrate, 170, securely, and also to minimize overspray of the deposited film onto the interior walls of the deposition chamber and rear face of the substrate, 170. The carrier, 100, in FIG. 1 can be modified to reduce the possibility of particles falling on or impacting the substrate by incorporation of any number of features as shown in U.S. prov. Appl. No. 62/420,127, herein incorporated by reference in its entirety.

FIG. 1 is a cross-section of a carrier, 100, holding a substrate, 170. The carrier, 100, includes a frame, 120, and at least one or more clamping mechanisms 100A for fixing and positioning the substrate, 170, such that it may be coated at the proper angle to minimize contamination. The carrier, 100, is designed to hold the substrate, 170, at an angle, φ (lower case phi), wherein φ is the angle difference between vertical (0°) and the angle of the downward tilt of the front face of the substrate 170. This tilt minimizes the possibility of airborne particles contacting and adhering to the substrate. φ should be sufficiently large enough to prevent any particles falling from the PVD chamber or top section, 110, of the frame from contacting the substrate, 170, but not so large that it induces a detrimental sag in the substrate, 170. In some embodiments, φ is from >0° to 10°, >0° to 8°, >0° to 5°, 1° to 8°, 1° to 5°, or 1° to 3°. The carrier, 100, may further include wheels, pulleys, tracks or other mechanisms or parts for moving the carrier 100 from one region of a coater to another, or into or out of the coater. Additional carrier parts may include mechanisms for positioning the carrier 100, loading and unloading the substrate from the carrier, cleaning the carrier, and the like.

As noted previously, frame 120 is the part of carrier 100 that surrounds the substrate 170 and provides structure to support the substrate 170 when vertically aligned for PVD coating. Due to the high temperatures possibly used in PVD coating processes, major components of the carrier 100 and frame 120 can be made from a metal, a glass, a ceramic, or a high temperature polymer. In some embodiments, the frame 120 comprises a metal. The metal may comprise aluminum, steel, such as stainless steel, titanium, or alloys or mixtures comprising these materials.

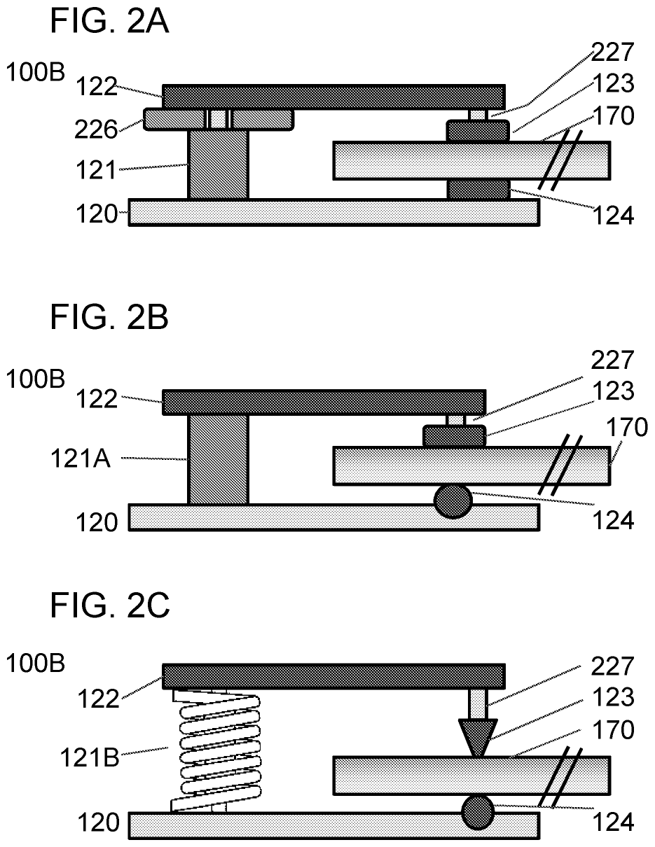

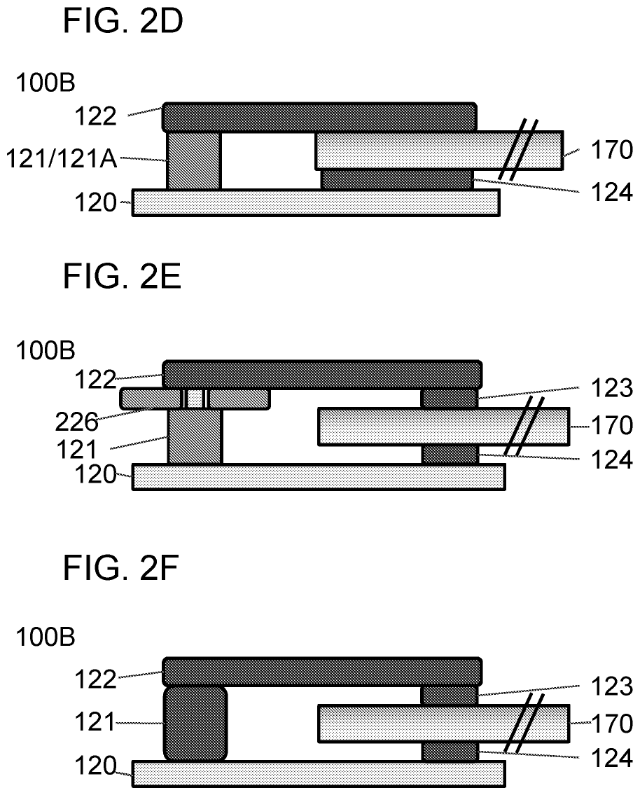

In some embodiments, the frame 120 can further comprise a channel or rib section, shown in FIGS. 2B, 3 and 4 as 121A. In some embodiments, the force applying tensioner 121 is on the channel section 121A. In some embodiments, the channel section 121A acts as the force applying tensioner 121 alone or in combination with a fastener, such as a bolt, screw, spring loaded mechanism, and the like (e.g., fastener 327).

Incorporated into or on the frame 120 is a protective spacer 124. The protective spacer 124 can comprise a bar, block, plate, rail, cylinder either oriented vertically or horizontally, and the like. FIG. 1 and FIGS. 2A-2F provide examples in cross section of possible configurations of the protective spacer 124. In some embodiments, such as FIG. 2B, the protective spacer 124 is at least partially incorporated into the frame—possibly via a groove or channel cut into the frame 120. In some embodiments, like FIG. 2A, the protective spacer 124 is on the surface of the frame. Because the protective spacer 124 contacts the substrate 170 and is meant to both hold it in place and allow it to move between the protective spacer 124 and the bumper 123 due to thermal changes, the protective spacer 124 can be made of a material that has a relatively low coefficient of friction (dynamic or static) and/or also has a low hardness to avoid scratching the substrate 170 when thermally cycling. In some embodiment, the dynamic coefficient of friction of the protective spacer material can be equal to or less than 0.5, 0.4, 0.3, 0.28, 0.25, 0.23, 0.2, 0.18, 0.15, 0.1, or 0.05 (dry vs. steel, QTM 55007). In some embodiments, the dynamic coefficient of friction of the protective spacer 124 material should be from 0.25 to 0.1 (dry vs. steel, QTM 55007). In some embodiments, where appropriate, the Moh's scale of hardness of any materials used should be equal to or less than 4.5, 4, 3.5, 3, 2.5, 2, 1.5, or 1. In some embodiments, the Moh's scale of hardness of any materials used for the protective spacer 124 should be from 3.5 to 1. Alternatively, in some embodiments, the protective spacer 124 comprises a material having a Rockwell E hardness of 130 or less, 120 or less, 110 or less, 100 or less, 90 or less, 80 or less, 70 or less, 60 or less, 50 or less, 40 or less, 30 or less, or 20 or less. The protective spacer 124 can be made from a high temperature polymer, paper or tape, or possibly a low hardness mineral, such as mica. In some embodiments, the protective spacer 124 comprises a polymer, such as a polybenzimidazole, a polyphenylsulfide, a polyarylsulfone, a fluoropolymer, or a polyarylethereketone.

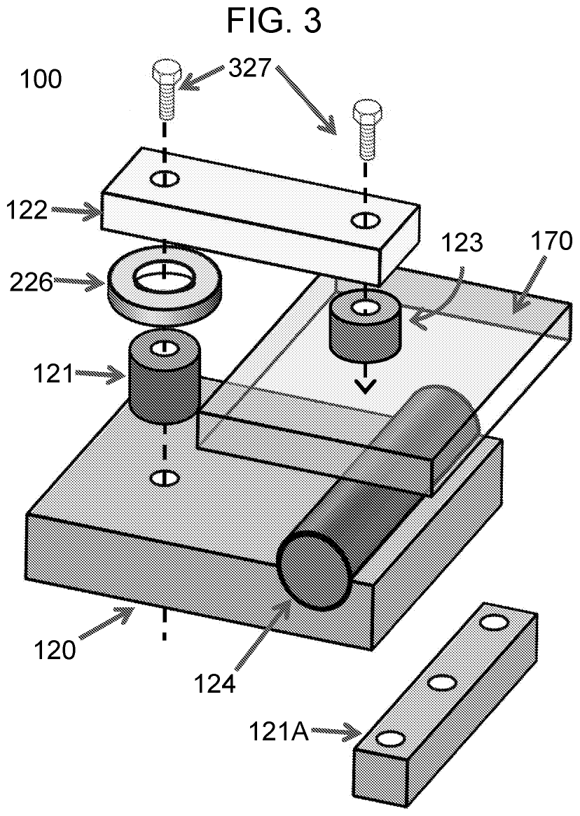

Force applying tensioner 121 either directly or indirectly connects frame 120 to rigid cantilever 122 and incorporates the mechanism that provides a holding force to the clamping mechanisms 100B. Each clamping mechanism 100B is designed to provide enough force to prevent unwanted sag in the glass, but not so much force that the glass can't move with the thermal variations it undergoes in the processes described herein. Each force applying tensioner 121 applies 40 N or less, 30 N or less, 25 N or less, 20 N or less, 18 N or less, 15 N or less, 12 N or less, or 10 N or less of force. In some embodiments, the force applying tensioner 121 provides spacing for the rigid cantilever 122 to offset it from the frame 120 and in some embodiments, provides a means for locking the rigid cantilever 122 in place. In some embodiments, the force applying tensioner 121 can comprise a spring, a shock, a fixed or solid object incorporating a spring or shock inside, or a fixed or solid object incorporating one or more threaded regions that allow for tightening down the rigid cantilever 122, or the like. For example, looking at FIG. 3, the force applying tensioner 121 is a spacer having a threaded region on the inside that allows for bolt 327 to clamp the rigid cantilever 122 down over spacer 226 and force applying tensioner 121. Alternatively, FIG. 3 provides for a force applying tensioner 121A that is a raised ridge or channel that connects to frame 120 and that acts in the same manner as 121. Channel force applying tensioners 121A can run along all or some of the sides of substrate 170.

Some embodiments further incorporate a shim, 226, that goes between the force applying tensioner 121 and the rigid cantilever 122 to ensure that forces are orthogonal to the face of the substrate 170 and that the rigid cantilever 122 does not accidently contact the substrate 170. The shim 226 can be made from a metal, a glass, a ceramic, or a high temperature polymer. In some embodiments, the shim 226 comprises a polymer, such as a polybenzimidazole, a polyphenylsulfide, a polyarylsulfone, a fluoropolymer, or a polyarylethereketone. In some embodiments, the shim 226 comprises a metal. The metal may comprise aluminum, steel, such as stainless steel, titanium, or alloys or mixtures comprising these materials.

The rigid cantilever 122 comprises a solid object that either directly or indirectly connects the bumper to the frame 120, typically through the force applying tensioner 121. In some embodiments, it comprises a relatively planar object designed to rotate about an axis orthogonal to the face of the frame 120 and substrate 170, such that after the substrate 170 is placed in the frame 120, the cantilevers 122can be positioned to place the bumper 123 approximately directly above the protective support 124 and then apply a force to the bumper. The rigid cantilever 122 may connect, either directly or indirectly to the force applying tensioner 121 and bumper 123 via screws, bolts, hinges, or may be welded, glued, or otherwise affixed to one or both. In some embodiments, the rigid cantilever 122, the force applying tensioner 121, and/or the bumper 123 may all comprise a single piece (see, e.g., FIG. 2F). In such an embodiment, there may be a single attachment point that connects the rigid cantilever 122 to the frame 120. The rigid cantilever 122 can be made from a metal, a glass, a ceramic, or a high temperature polymer. In some embodiments, the rigid cantilever 122 comprises a polymer, such as a polybenzimidazole, a polyphenylsulfide, a polyarylsulfone, a fluoropolymer, or a polyarylethereketone. In some embodiments, the rigid cantilever 122 comprises a metal. The metal may comprise aluminum, steel, such as stainless steel, titanium, or alloys or mixtures comprising these materials.

Connected, either directly or indirectly, to the rigid cantilever 122, is the bumper 123. The bumper 123 can comprise a point, cone, ball, bar, block, plate, rail, cylinder either oriented vertically or horizontally, and the like. FIG. 1 and FIGS. 2A-2F provide examples in cross section of possible configurations of the bumper 123. In some embodiments, such as FIGS. 2A-2C, the bumper 123 is attached to the rigid cantilever 122 by a shaft 227. The shaft 227 can be made of the same material as either the rigid cantilever 122 the bumper 123 or of another material. Because the bumper 123 contacts the substrate 170 and is meant to both hold it in place and allow it to move between the protective spacer 124 and the bumper 123 due to thermal changes, the bumper 123 much be made of a material that has a relatively low coefficient of friction and also has a low hardness to avoid scratching the substrate 170 when thermally cycling. The dynamic coefficient of friction of the bumper 123 should be equal to or less than 0.5, 0.4, 0.3, 0.28, 0.25, 0.23, 0.2, 0.18, 0.15, 0.1, or 0.05 (dry vs. steel, QTM 55007). In some embodiments, the dynamic coefficient of friction of the bumper material should be from 0.25 to 0.1 (dry vs. steel, QTM 55007). The Moh's scale of hardness of any materials used should be equal to or less than 4.5, 4, 3.5, 3, 2.5, 2, 1.5, or 1. In some embodiments, the Moh's scale of hardness of any materials used for the protective spacer 124 should be from 3.5 to 1. The bumper 123 can be made from a high temperature polymer, paper or tape, or possibly a low hardness mineral, such as mica. In some embodiments, the bumper 123 comprises a polymer, such as a polybenzimidazole, a polyphenylsulfide, a polyarylsulfone, a fluoropolymer, or a polyarylethereketone. Typically, the bumper 123 and the protective spacer 124 are made of the same material to avoid introducing any out of plane stresses. Further, in some embodiments, the bumper 123 is designed to contact the glass opposite to the protective spacer 124 such that the forces on the glass are approximately equal and orthogonal to plane of the substrate faces.

Substrates that can be used in the carrier 100 described herein include those made of glass, glass ceramic, polymer or plastic, such as polyacrylics, polycarbonates, crystalline materials, such as sapphire, and minerals.

Now turning to FIGS. 2A-2F, as stated above, the embodiments in these figures provide examples of the clamping mechanism 100B in carrier 100. FIG. 2A provides a frame 120 connected to a force applying tensioner 121 that connects to the rigid cantilever 122, with a spacer 226 controlling spacing between 121 and 122. The substrate 170 is held in place between the bumper 123 and the protective spacer 124, with the bumper 123 connecting to the rigid cantilever 122 via a shaft 227. FIG. 2B shows a similar design, but where the protective spacer 124 is now circular in cross section and is embedded in the frame 120. FIG. 2C is an alternative design where the force applying tensioner 121B comprises a spring and no spacer 226 is present. Further, the bumper 123 has a more conical form that provides a more focused force on a particular region of the substrate 170. FIG. 2D is an example embodiment where the bumper 123 has been removed or essentially incorporated into the rigid cantilever 122. In such an embodiment, the rigid cantilever 122 can comprise or be coated with a low coefficient of friction material and/or a low hardness material to avoid damaging the substrate. Further, the protective spacer 124 needs to be extended such that the force is even across the substrate 170 surface to avoid unwanted stresses. FIGS. 2E and 2F are similar in design, but in FIG. 2E, the rigid cantilever 122 is directly connected to force applying tensioner 121, such as if 121 were a metal channel on the back of the frame 120. FIG. 2F is similar, but in this case, the force applying tensioner 121, the rigid cantilever 122, and the bumper 123 comprise a single element made of the same material.

FIG. 3 presents a breakdown of the basic elements of the embodiments described herein. The frame 120, spacer 226, rigid cantilever 122, bumper 123 (including a threaded center to allow for connecting to the rigid cantilever 122 via bolt 327, protective spacer 124 and substrate 170 are all described above. The force applying tensioner 121 is shown in this diagram as a fixed part with interior threading for a bolt 327, and is also shown in the alternative as a channel force applying tensioner element 121A that runs along the back of the frame 120 and can have multiple contact points for multiple rigid cantilevers (as shown).

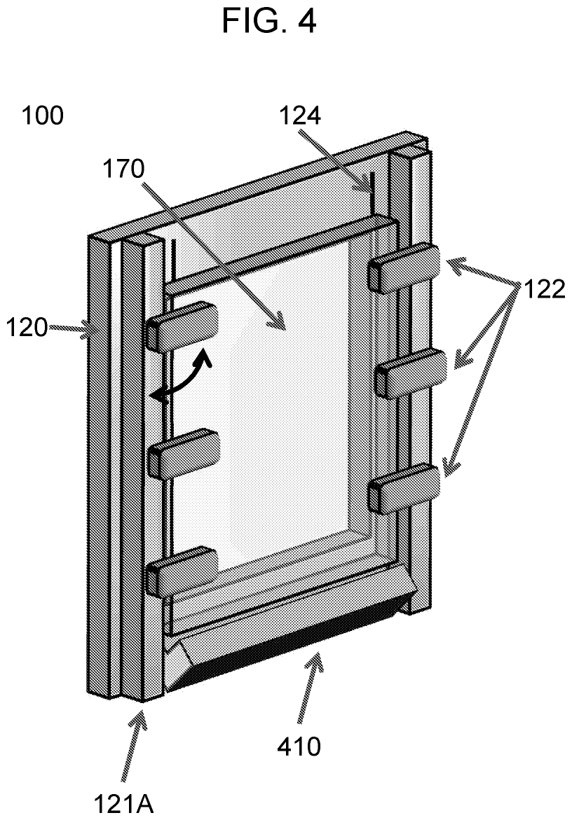

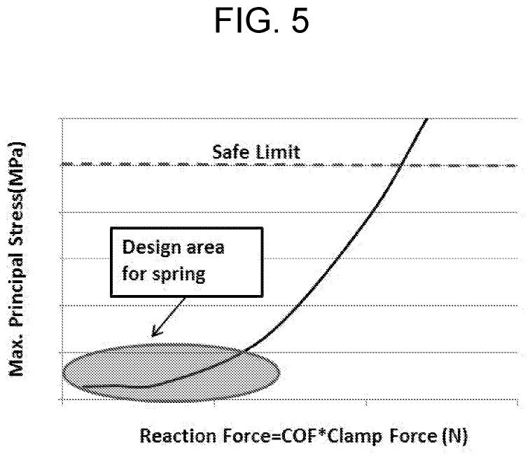

FIG. 4 is a pictorial representation of the carrier 100 with six (three on each side) clamping mechanisms 100B attached to force applying tensioner elements 121 and holding in substrate 170. The clamping mechanisms 100B hold the substrate 170 in place by pressing it against the protective spacer 124 via the bumper (not shown) while it undergoes PVD coating, and in some cases while the substrate 170 is moved through the various process steps. FIG. 4 further includes an optional channel groove 410 along the bottom of the frame 120. The channel groove 410 provides low pressure support for the substrate 170. The channel groove 410 is made of a material that is unlikely to scratch or damage the substrate. It may be made of the same material as the protective spacer 124 or the bumper 123. Generally, high temperature polymers can be used for the channel groove 410.

In addition to carrier angle, there are non-geometric approaches to particle reduction that may be used separately or in combination. In particular, the adhesion of the deposited film to the metal surfaces may be enhanced to reduce or delay flaking and particle generation. One method for modifying adhesion is by controlling the roughness of carrier 100 and/or frame 120 surfaces, such as through sand blasting or mechanical abrasion. In some embodiments, it is advantageous to roughen the surface to a value of 500 nm to 100 μm, 1 μm to 100 μm, 500 nm to 50 μm, 1 μm to 75 μm, 1 μm to 50 μm, 1 μm to 25 μm, 1 μm to 10 μm, 500 nm to 10 μm, 500 nm to 5 μm, or 1 μm to 5 μm.

Adhesion can also be modified by using an intermediate coating. Coatings may comprise, for example, copper, chromium, titanium, nickel, or combinations or oxides thereof. Coatings can be applied by known means, such as electrolytic coating or twin-wire arc spray and could be deposited onto the carriers during routine maintenance.

While the embodiments described herein are directed to a substrate having a square or rectangular configuration, the apparatus and processes described are equally applicable to any substrate with any alternative shape. For example, the processes and apparatus described herein would be equally applicable to a round, triangular, or other geometric shaped substrate. Such embodiments may necessitate changes in the carrier 100, the frame 120, or sections of the frame, but otherwise should generally not need substantive modification.

Substrates that can be used in the applications described herein include any that survive the PVD processes. Primarily this comprises glass and glass ceramic substrates, but may also include some metals and high temperature polymers.

The carrier 100 described herein can be used in many processes where there is a need to coat substrates with little to no contamination by remnant particles. While it is particularly useful for PVD, it could also be used in coating processes such as chemical vapor deposition, sputtering deposition, electron beam deposition, pulsed laser deposition, molecular beam epitaxy, or ion beam deposition. Use of the carrier in these processes is relatively straightforward with the substrate being placed in the carrier, properly affixed, and then placed in the thin film coating device and subjected to coating. Depending on the coating process, it may be necessary to optimize the tilt angle of the substrate to minimize the amount of particulate contamination that accumulates on the substrate.

### EXAMPLES

The following examples are put forth so as to provide those of ordinary skill in the art with a complete disclosure and description of how the materials, articles, and methods described and claimed herein are made and evaluated, and are intended to be purely exemplary and are not intended to limit the scope of the description. Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, desired solvents, solvent mixtures, temperatures, pressures and other reaction ranges and conditions that may be used to optimize the product purity and yield obtained from the described process. Only reasonable and routine experimentation will be required to optimize such process conditions.

### Example 1

This embodiment is generally described in FIG. 4 and provides a frame 120 designed to attach to the internal “window” area of a near vertical carrier 100 used in a large scale PVD sputtering process. The perimeter or mask area of the front side (side to be coated) of the thin glass 170 rests on the frame section 120. The frame section 120 has clamping mechanisms 122 that are lifted slightly (away from the frame) and then rotated to a position where a bumper (or bumpers) 123 rests on the back of the glass substrate 170 in an area adjacent to the edge. In the example, are several bumpers 123 positioned around the perimeter of the glass substrate. Additionally, on the lower side of the glass substrate 170 the edge of the substrate rests in a grooved block 410. The grooved block 410 is designed to have a slight amount of compliance to minimize the potential of chipping the edge.

Frame sections 120 are secured in place to horizontal “tap” bars on bottom and top inside perimeter of carrier 100. The key metal components to these frame sections are the frame portion 120 which is parallel to the glass sheet and channel section 121A which is perpendicular to the glass sheet. Between the frame and the substrate 170, is a protective spacer. A groove can be milled into frame to allow capture of this protective spacer 124 or a pad of plastic material may be bolted to frame to provide the glass contact area. Any bolts are recessed into plastic pad to prevent contact with the glass. In FIG. 4, the frame 120 has high temperature plastic dowels 124 pressed into it to prevent direct contact of glass to metal. Alternative designs allow disks or thin blocks of high temperature plastic to bolt or be fixed to frame 120. The spacing of the dowels or blocks to the edge of the frame prevents glass contact during processing.

The channel 121A is also where the cantilever 122 of the clamping mechanism 100A is secured. Clamp force is limited by the use of spring weight and minimizing clamp travel with shims 226. The channel is drilled and bored to create a pocket where a spring is retained. A shoulder bolt is placed through spring in that pocket and then threaded into the top plate of the clamp. A shim 226 of a certain thickness is used to limit the range of the clamping motion. The clamping motion (force) can be greater on the clamps securing the top edge of the glass to minimize sag. The clamping motion can be lesser on the corners, side and bottom clamps of the glass to keep the glass from moving excessively and allow for differences in thermal expansion of glass and grid/frame components

The combination of springs and shims in various locations minimizes the amount of sag observed (<6 mm out of plane displacement) in the glass. Modeling of 1930 mm tall by 3150 mm wide by 0.7 mm thick glass agrees with this observation. Calculation based on distance from the PVD sputter target would suggest the sag observed would result in <10% variation of film uniformity from top to bottom of thin glass. The frame depth (amount of frame overlapping the edge perimeter of glass) is minimized to maintain high glass utilization while also minimizing sag

The frame is designed to be attached to a larger vertical carrier and inserted into the PVD device. This design minimizes rotation of the frame members that would twist the glass out of plane/flatness, but allow for differences in expansion due to coefficient of thermal expansion, thermal transfer or overall mass of individual components of the frame/carrier system. This in combination with the spring and shims associated with the clamp maintain low reaction force. This results in near zero material loss in the heating or cooling process steps. Spring selection allows for low reaction force, which results in maximum principle stress well below safe limit for thin glass (FIG. 7).

The embodiments described herein allow for easy loading of glass and then manual rotating of clamp to secure. Tolerances are set in fabrication to allow sufficient clearance to allow parts to freely move while maintaining alignment throughout a variety of thermal conditions. All clamps are rotated to the open position before glass loading. The bottom edge of the glass is set in the grooves of the bottom compliant, high temperature plastic blocks first. Glass is aligned left to right to ensure that edge of glass will not contact sides of frame. Glass is then tilted forward to be in contact with the side then top plastic dowels or blocks that are on the frame surface

The top middle clamps are then lifted and rotated to the closed position. Care is taken to release the clamps gently onto the glass so no checking occurs. Then the remaining top, side then bottom clamps are moved to the closed position.

1. An article comprising:
a frame for holding a substrate in an approximately vertical configuration in a thin film deposition system containing a coating device, the frame being dimensionally larger than the substrate, and wherein the substrate has at least a front face, a back face, and at least one edge;
the frame comprising:
a) a flat frame section and a channel section, wherein when the article is in the thin film deposition system, the flat frame section is positioned between the coating device and at least part of the substrate, and the channel section is positioned adjacent to the at least one substrate edge;
i. the flat frame section comprising a protective spacer that contacts the substrate on the front face, the protective spacer comprising a material that will not scratch the surface of the substrate; and
two or more clamps comprising:
a) a bumper that contacts the substrate on the back face, the bumper comprising a material that will not scratch the surface of the substrate;
b) a rigid cantilever directly or indirectly connecting the channel section to the bumper; and
c) a force-applying tensioner mechanism that provides a reaction force of less than 25 N on the substrate;
wherein the article is designed so that when a substrate is in the frame, the substrate is held at an angle φ of from greater than 0° to about 10° forward tilt and experiences a maximum principal stress of less than 100 MPa while undergoing thermal variations of from 17 min to 40°/min over a range of from 0° C. to 400° C.

2. The article of claim 1, wherein the bumper and protective spacer are made of an organic polymer.

3. The article of claim 1, wherein the maximum principal stress is 80 MPa or less.

4. The article of claim 1, wherein the reaction force is less than 15 N.

5. The article of claim 1, wherein the substrate is held at an angle φ of from greater than 0° to about 3° forward tilt.

6. The article of claim 1, wherein the two or more clamps are each rotatable on an axis orthogonal to the substrate faces.

7. The article of claim 1 any of claims 1, wherein an imaginary line orthogonal to the back face of the substrate and passing through a point where the bumper contacts the substrate would also pass through the protective spacer.

8. An article comprising:
a frame for holding a substrate in an approximately vertical configuration in a thin film deposition system containing a coating device, the frame being dimensionally larger than the substrate, and wherein the substrate has at least a front face, a back face, and at least one edge;
the frame comprising:
a) a flat frame section, wherein when the article is in the thin film deposition system, the flat frame section is positioned between the coating device and at least part of the substrate;
i. the flat frame section comprising a protective spacer that contacts the substrate on the front face, the protective spacer comprising a material that will not scratch the surface of the substrate; and
two or more clamps comprising:
a) a cantilever spacer directly or indirectly connecting the cantilever to the frame;
b) an optional bumper that contacts the substrate on the back face, the bumper comprising a material that will not scratch the surface of the substrate;
c) a rigid cantilever directly or indirectly connecting the cantilever spacer to the bumper, wherein when the optional bumper is not present, the rigid cantilever contacts the substrate on the back face and comprises a material that will not scratch the surface of the substrate; and
d) a force-applying tensioner mechanism that provides a reaction force of less than 25 N on the substrate;
wherein the article is designed so that when a substrate is in the frame, the substrate is held at an angle φ of from greater than 0° to about 10° forward tilt and experiences a maximum principal stress of less than 100 MPa while undergoing thermal variations of from 5°/min to 40°/min over a range of from 0° C. to 300° C.

9. The article of claim 8, wherein the bumper and protective spacer are made of an organic polymer.

10. The article of claim 8 or claim 9, wherein the maximum principal stress is 80 MPa or less.

11. The article of claim 8, wherein the reaction force is less than 15 N.

12. The article of claim 8, wherein the substrate is held at an angle φ of from greater than 0° to about 3° forward tilt.

13. The article of claim 8, wherein the two or more clamps are each rotatable on an axis orthogonal to the substrate faces.

14. The article of claim 8, wherein an imaginary line orthogonal to the back face of the substrate and passing through a point where the bumper contacts the substrate would also pass through the protective spacer.

15. An article comprising:
a frame for holding a substrate in an approximately vertical configuration in a thin film deposition system containing a coating device, the frame being dimensionally larger than the substrate, and wherein the substrate has at least a front face, a back face, and at least one edge;
the frame comprising:
a) a flat frame section, wherein when the article is in the thin film deposition system, the flat frame section is positioned between the coating device and at least part of the substrate;
i. the flat frame section comprising a protective spacer that contacts the substrate on the front face, the protective spacer comprising a material that will not scratch the surface of the substrate; and
two or more clamps comprising:
a) an optional bumper that contacts the substrate on the back face;
b) an organic polymer cantilever incorporating a cantilever spacer and that directly or indirectly connects the frame to the bumper, wherein when the optional bumper is not present, the rigid cantilever contacts the substrate on the back face and comprises a material that will not scratch the surface of the substrate; and
c) an optional force-applying tensioner mechanism that provides a reaction force of less than 25 N on the substrate;
wherein the article is designed so that when a substrate is in the frame, the substrate is held at an angle φ of from greater than 0° to about 10° forward tilt and experiences a maximum principal stress of less than 100 MPa while undergoing thermal variations of from 5°/min to 40°/min over a range of from 0° C. to 300° C.

16. The article of claim 15, wherein the bumper and protective spacer are made of an organic polymer.

17. The article of claim 15, wherein the maximum principal stress is 80 MPa or less.

18. The article of claim 15, wherein the reaction force of less than 15 N.

19. The article of claim 15, wherein the substrate is held at an angle φ of from greater than 0° to about 3° forward tilt.

20. The article of claim 15, wherein the two or more clamps are each rotatable on an axis orthogonal to the substrate faces.

21. The article of claim 15, wherein an imaginary line orthogonal to the back face of the substrate and passing through a point where the bumper contacts the substrate would also pass through the protective spacer.
